(19) United States
(12) Patent Application Publication
(10) Pub. No.: US 2003/0227080 A1
(43) Pub. Date: Dec. 11, 2003

(54) Multi-chip module

(75) Inventor: Koji Goto, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/301,620

(22) Filed: Nov. 22, 2002

(30) Foreign Application Priority Data
Jun. 11, 2002 (JP) 2002-170439

(51) Int. Cl. H01L 23/34

(52) U.S. Cl. 257/723

(57) ABSTRACT

Two integrated circuit chips, for instance, are disposed on a substrate such that the top surfaces of these integrated circuit chips are located within the same plane surface. A spacer having substantially the same coefficient of thermal expansion as the one of the integrated circuit chips is disposed between the integrated circuit chips. Wiring is formed on the spacer by means of lithography technology.

### BACKGROUND OF THE INVENTION

1. Field of the Invention

The present invention relates to a multi-chip module in which wirings connected between at least a plurality of integrated circuit chips are performed by means of lithography technology, and more particularly relates to a manufacturing method of the multi-chip module.

2. Description of the Prior Art

Conventionally, the multi-chip module of this type and the manufacturing method thereof have been disclosed in JP-A 8-162604 (1996) and JP-A 2001-35993, for instance. The wirings of the multi-chip modules described in these unexamined publications are formed by means of lithography technology including photoresist application, photomask alignment, exposure, development, etching, photoresist removal, and so on.

FIG. 15 is a sectional view of a conventional multi-chip module disclosed in JP-A-8-162604 (1996). Referring to the figure, reference numeral 1 denotes a structural substrate made of silicon; 2 denotes planarizing material formed of polyimide (or spin-on glass and the like) applied over the top surface of the substrate 1; 3 denotes a plurality of IC chips buried in the planarizing material 2; 4 denotes the surface side of the IC chips 3; 5 denotes an interlayer film formed of polyimide (or spin-on glass and the like) applied on the surface side 4 of the IC chips 3; 6 denotes a leading portion of the chip wiring, formed by means of lithography technology; 7 denotes an aluminum wiring formed by means of lithography technology; and 8 denotes a protective film made of polyimide (or spin-on glass and the like).

FIG. 16 is a sectional view of the multi-chip module disclosed in JP-A 2001-35993. Referring to the figure, reference numeral 11 denotes an island located at the center of the lead frame (not shown); 12 denotes an DRAM chip and a logic circuit chip each bonded on the surface of the island 11; 13 denotes an interlayer insulation film formed of polyimide (or spin-on glass (film) or the like) formed over the chips 12; 14 denotes a connection hole formed through the interlayer insulation film 13 by means of lithography process; 15 denotes a W plug buried in each of the connection holes 14; 16 denotes an interchip wiring connected between the W plugs 15 located inside and made of Al; 17 denotes a bonding pad connected with the W plug 15 located outside and made of Al; and 18 denotes a passivation film formed over the interchip wiring 16 and the bonding pads 17.

The conventional multi-chip module is arranged as mentioned above. The multi-chip module is arranged for the purpose of operating in a severe temperature variation of −40 to +100° C. However, because the chip 3 or chip 12 is in contact with the polyimide (or spin-on glass and the like), strain is produced between the chip 3 or chip 12 and the polyimide (or spin-on glass and the like) because of the difference between their coefficients of thermal expansion. The chip 3, 12, and/or the wiring 7, 16 could be-thereby broken at worst.

Moreover, in the conventional multi-chip modules, a plurality of chips 3 are horizontally disposed on the substrate 1, or a plurality of chips 12 are horizontally disposed on the island 11. For this reason, the bulk of a plurality of chips 3 in the horizontal direction within the substrate 1 or the bulk of a plurality of the chips 12 in the horizontal direction within the island 11 becomes large. As a result, there has been a problem that the mounting area occupied by a plurality of chips. 3 within the substrate 1, or the mounting area occupied by a plurality of chips 12 within the island 11 becomes too large with respect to the area of the substrate or the island.

### SUMMARY OF THE INVENTION

The present invention has been accomplished to solve the above-mentioned problem. An object of the present invention is to provide a multi-chip module in which its reliability under conditions in which the temperature changes can be improved and a manufacturing method thereof.

In addition, another object of the present invention is to provide a multi-chip module in which the chip mounting area therein can be reduced.

According to a first aspect of the present invention, there is provided a multi-chip module in which a material having substantially the same coefficient of thermal expansion as that of the integrated circuit chips is disposed between the integrated circuit chips, and the wiring is formed on the material.

Therefore, an extremely great number of fine wirings can be formed primarily. Moreover, because strain is not produced between the integrated circuit chip and the material even if the temperature changes, the integrated circuit chip and the wiring are not damaged, thereby improving the reliability of the module to a temperature change.

In addition, according to a second aspect of the present invention, there is provided a multi-chip module in which a plurality of integrated circuit chips are stacked on the substrate in the vertical direction with respect to the substrate.

Therefore, the mounting area of the plurality of integrated circuit chips within the substrate can be reduced with respect to the substrate area, thereby improving design flexibility.

Further, according to a third aspect of the invention, there is provided a manufacturing method of the multi-chip module which includes the step of disposing a material having substantially the same coefficient of thermal expansion as that of the integrated circuit chips between the integrated circuit chips, and the step of forming the wiring on the material.

### BRIEF DESCRIPTION OF THE DRAWINGS

FIG. 1 is a fragmentary sectional view showing the multi-chip module in accordance with an embodiment 1 of the present invention;

FIG. 2 is an explanatory diagram of the manufacturing process of the multi-chip module in accordance with the embodiment 1 of the present invention;

FIG. 3 is an explanatory diagram of the manufacturing process of the multi-chip module in accordance with the embodiment 1 of the present invention;

FIG. 4 is an explanatory diagram of the manufacturing process of the multi-chip module in accordance with the embodiment 1 of the present invention;

FIG. 5 is a fragmentary sectional view showing the multi-chip module in accordance with an embodiment 2 of the present invention;

FIG. 6 is a fragmentary sectional view showing the multi-chip module in accordance with an embodiment 3 of the present invention;

FIG. 7 is a fragmentary sectional view showing the multi-chip module in accordance with an embodiment 4 of the present invention;

FIG. 8 is a fragmentary sectional view showing the multi-chip module in accordance with an embodiment 5 of the present invention;

FIG. 9 is an explanatory diagram of the manufacturing process of the multi-chip module in accordance with the embodiment 5 of the present invention;

FIG. 10 is an explanatory diagram of the manufacturing process of the multi-chip module in accordance with the embodiment 5 of the present invention;

FIG. 11 is an explanatory diagram of the manufacturing process of the multi-chip module in accordance with the embodiment 5 of the present invention;

FIG. 12 is an explanatory diagram of the manufacturing process of the multi-chip module in accordance with the embodiment 5 of the present invention;

FIG. 13 is an explanatory diagram of the manufacturing process of the multi-chip module in accordance with the embodiment 5 of the present invention;

FIG. 14 is an explanatory diagram of the manufacturing process of the multi-chip module in accordance with the embodiment 5 of the present invention;

FIG. 15 is a sectional view showing a multi-chip module in accordance with a conventional technology; and

FIG. 16 is a sectional view showing a multi-chip module in accordance with a conventional technology.

### DETAILED DESCRIPTION OF THE PREFERRED EMBODIMENTS

An embodiment of the present invention will be described below.

Embodiment 1

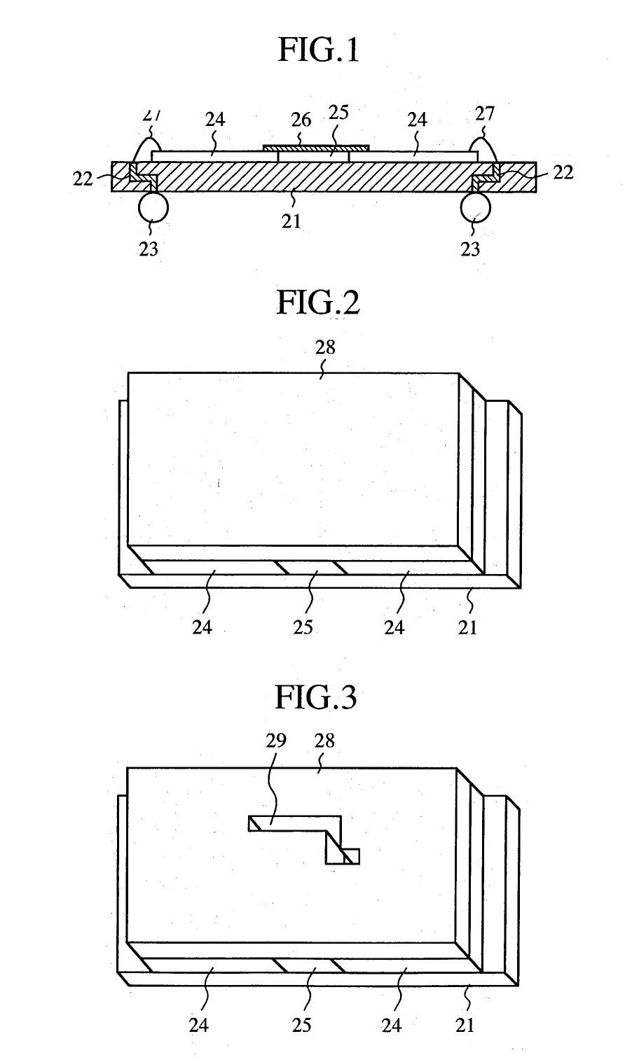

FIG. 1 is a fragmentary sectional view showing the multi-chip module in accordance with an embodiment 1 of the present invention. Referring to the figure, reference numeral 21 denotes a substrate made of silicon or the like; 22 denotes an internal wiring formed within the substrate 21; 23 denotes a bump of a ball grid array (BGA), disposed on the bottom surface of the substrate 21; 24 denotes one of two integrated circuit chips, for instance, having a function different from each other, bonded on the top surface of the substrate 21; 25 denotes a spacer (material) that is of square cross-section, bonded on the top surface of the substrate 21 between the integrated circuit chips 24, 24; 26 denotes a fine wiring formed of aluminum or the like for electrically connecting the integrated circuit chips 24, 24; and 27 denotes a bonding wire formed of gold or the like for electrically connecting the internal wiring 22 and the integrated circuit chips 24, 24. The wiring 26 is diagonally shaded for clarity of illustration.

The integrated circuit chips 24, 24, and the spacer 25 are arranged to have the same thickness, and are also arranged such that the top surfaces thereof are located within the same plane. Both the end faces of the spacer 25 are connected with the end faces of the integrated circuit chips 24, 24, respectively, in end-to-end relationship. In addition, the integrated circuit chips 24, 24, the spacer 25, and the wiring 26 are protected by use of a passivation film or the like (not shown).

Herein, the spacer 25 is formed of a material having substantially the same coefficient of thermal expansion as the one of the integrated circuit chips 24 and 24. The wiring 26 is formed by means of lithography technology that is the similar process to the one used for manufacturing integrated circuits or printed circuit boards. The lithography technology includes the steps of oxidation, photoresist applying, photomask aligning, photoresist exposing, photoresist developing, etching, and photoresist removing.

The manufacturing method of the multi-chip module will now be described as below.

As shown in FIG. 2, the integrated circuit chips 24, 24, and the spacer 25 are first closely aligned at the predetermined position on the substrate 21, and then the bottom surfaces thereof are bonded to the substrate 21. A photoresist having photosensitivity is applied over the top surfaces of the integrated circuit chips 24, 24, and the spacer 25, and thereby photoresist film 28 is formed.

Subsequently, a photomask (not shown) having the pattern of the wiring 26 is aligned thereon, the photoresist film 28 is irradiated with light through the photomask, and the photoresist film 28 is exposed to have the exposed pattern of the wiring 26 therein. Thereby, the exposed portion of the photoresist film 28 turns into insoluble film (portion) in a specific solvent. Accordingly, when developing the photoresist film 28 with the solvent, the unexposed portion thereof is solved therein, to thereby create wiring hole 29 for forming the wiring 26 therethrough as shown in FIG. 3.

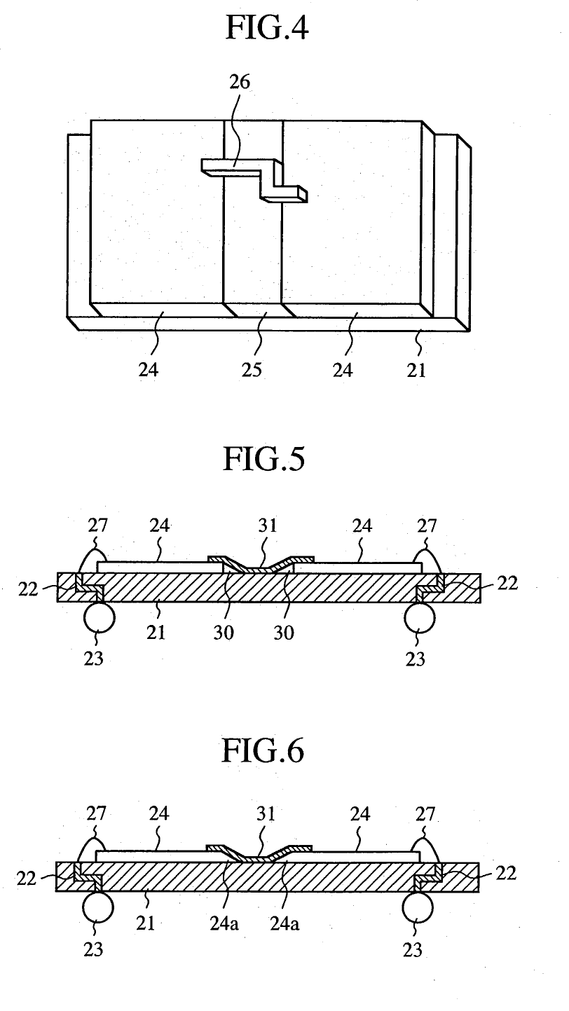

Then, aluminum, for instance, serving as the material for the wiring 26 is deposited within the wiring hole 29 by means of evaporation or plating, to thereby fill the hole. When removing the remaining photoresist film 28 by means of etching the film, only fine wiring 26 used for electrically connecting the integrated circuit chips 24, 24 remains as shown in FIG. 4. Subsequently, the integrated circuit chips 24, 24, the spacer 25, and the wiring 26 are coated and protected with passivation film (not shown). Then, the internal wiring 22 and the integrated circuit chips 24, 24 are electrically connected by use of bonding wires 27.

As mentioned above, in accordance with the embodiment 1, because the spacer 25 having substantially the same coefficient of thermal expansion as the one of the integrated circuit chips 24, 24 is disposed between them, strain is not produced between the integrated circuit chips 24, 24 and the spacer 25 even if the temperature changes. Accordingly, the integrated circuit chips 24 and the wiring 26 are not damaged, thereby improving the reliability of the module for temperature changes. The manufacturing method can be easily applied to the conventional multi-chip module, which is put in a state in which the integrated circuit chips 24, 24 are bonded to the substrate 21, by simply disposing only spacer 25 between the integrated circuit chips 24, 24.

Additionally, because the top surfaces of the integrated circuit chips 24, 24, and the spacer 25 are located within the same plane, and both of the end faces of the spacer 25 are connected with the end faces of the integrated circuit chips 24, 24, respectively, in end-to-end relationship, the photoresist does not flow into the gap between the integrated circuit chips 24, 24. Accordingly, the surface of the photoresist film 28 easily becomes flattened and thereby the accuracy of the wiring 26 will be improved.

In addition, because the wiring 26 was formed by means of lithography technology, the number of wires of the wiring 26 was extremely increased in comparison with that in the conventional wire wiring, and thereby the load capacity of the wiring 26 was reduced. As a result, the operation between the integrated circuit chips 24, 24 can be performed by use of a buffer circuit or the like in place of a usual I/O circuit. Therefore, the buffer circuit can be built by use of a circuit that performs as well as an internal element within the integrated circuit chips 24, and thereby the extremely high integration of semiconductor devices becomes possible. Additionally, not only the speed of a signal transmitted between the integrated circuit chips 24, 24 will be improved to the same level as a signal transmitted within the integrated circuit chip 24, but also the power consumption will be reduced when compared with the one using the I/O circuit.

Further, because the integrated circuit chip 24 can be separately produced, the production is performed in extremely improved yield and at lower cost than when producing the device by use of a one-chip structure. When the integrated circuit chip 24 is a DRAM chip, a logic circuit chip, or an analog circuit chip, the DRAM chip can be produced without using an expensive process; the logic circuit chip can be produced by use of a state-of-the-art microfabrication process; and the analog circuit chip can be produced by use of a process of an old type because of its inexpensiveness and high voltage resistance. That is, the multi-chip module can be produced at low cost by use of the most favorable processes with respect to the yields and characteristics of the required integrated circuit chips.

Embodiment 2

FIG. 5 is a fragmentary sectional view showing the multi-chip module in accordance with an embodiment 2 of the present invention. A single pair of spacers (materials) 30, 30 that are of right-angled triangular cross-section are separately symmetrically disposed therein instead of the spacer 25 that is of square cross-section of the embodiment 1. Wiring 31 is formed on the top surfaces of the spacers 30, 30, and of substrate 21 by means of lithography technology. This multi-chip module is similar to that of the embodiment 1 excepting that mentioned above.

The spacers 30, 30 are formed of the similar material to that of the spacer 25 used in the embodiment 1. The vertical face of the spacer 30 is connected with an end face of the integrated circuit chip 24 in end-to-end relationship such that the vertical face and the end face have the same height. The spacer 30 has an oblique surface (face) formed as being gradually slanted down. Wiring 31 is formed over the oblique surface of one spacer 30, the top surface of the substrate 21 and the oblique surface of the other spacer 30.

As mentioned above, in accordance with the embodiment 2, because the spacer 30 is formed of the similar material to the spacer 25 used in the embodiment 1, strain is not produced between the integrated circuit chips 24 and the spacer 30 even if the temperature changes. Accordingly, the integrated circuit chips 24 and the wiring 26 are not damaged, thereby improving the reliability of the module for temperature changes. In addition, similarly to the embodiment 1, the manufacturing method can be easily applied to the conventional multi-chip module, which is put in a state in which the integrated circuit chips 24, 24 are bonded to the substrate 21, by simply disposing only the spacers 30, 30 between the integrated circuit chips 24, 24.

Embodiment 3

FIG. 6 is a fragmentary sectional view showing a multi-chip module in accordance with an embodiment 3 of the present invention. Instead of the spacers 30, 30 that are of right-angled triangular cross-section of the embodiment 2, there are provided spacer portions (materials) 24a, 24a that have a similar shape to them, and are previously disposed as a unit with the same material as the one of the integrated circuit chips 24, 24, in these chips, respectively. Wiring 31 that is similar to that shown in the embodiment 2 is formed over the top surfaces of the spacer portions 24a, 24a of the chips, and of the substrate 21 by means of lithography technology. The multi-chip module is similar to that in the embodiment 2 except for that mentioned above.

As mentioned above, in accordance with the embodiment 3, because the spacer portions 24a, 24a are previously disposed as a unit in the integrated circuit chips 24, 24, respectively, strain is not produced within the integrated circuit chips 24, 24 even if the temperature changes. Therefore, the similar effect to the embodiment 2 is obtained. Moreover, the process for disposing the spacers 30, 30 performed in the embodiment 2 becomes unnecessary. As a result, the productivity of the multi-chip modules can be improved as compared with the embodiment 2.

Embodiment 4

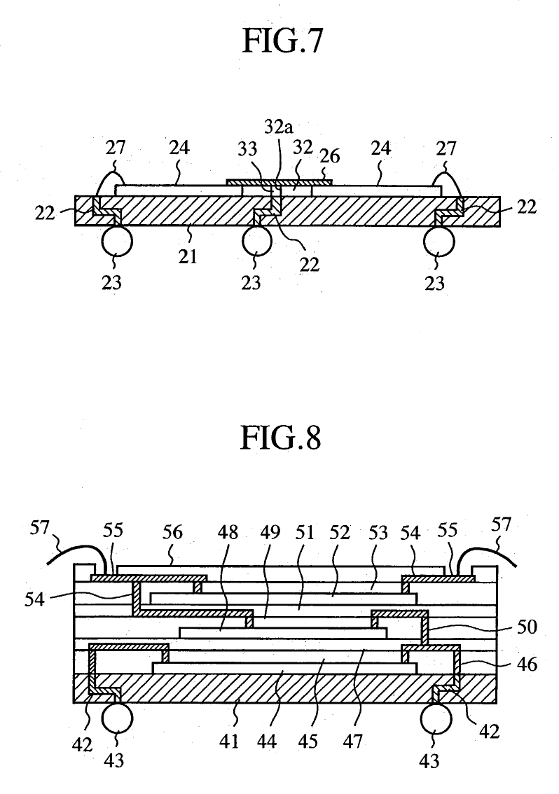

FIG. 7 is a fragmentary sectional view showing the multi-chip module in accordance with an embodiment 4 of the present invention. Internal wiring 22 and bump 23 are formed almost at the lateral center of the substrate 21, and simultaneously spacer 32 having a through hole 32a and a similar shape to the spacer 25 in the embodiment 1 is disposed therein instead of the spacer 25. The through hole 32a has plug 33 formed therein, and the plug 33 is connected with the top end of the internal wiring 22 located at the center. Wiring 26 that is similar to that in the embodiment 1 is formed on the top surface of the spacer 32 by means of lithography technology, and the wiring 26 is electrically connected with the plug 33.

As mentioned above, in accordance with the embodiment 4, the similar effect to the embodiment 1 is obtained. Moreover, when the spacer 32 having a through hole 32a is disposed between the integrated circuit chips 24, 24, the wiring 26 can be connected with the bump 23 through the plug 33 formed within the through hole 32a and the internal wiring 22 formed inside the substrate 21. Therefore, the wiring including the I/O buffer of the usual integrated circuit chips 24, 24 can be formed.

Embodiment 5

FIG. 8 is a fragmentary sectional view showing the multi-chip module in accordance with an embodiment 5 of the present invention. Referring to the figure, reference numeral 41 denotes a similar substrate to the substrate 21 of the embodiment 1; 42 denotes a similar internal wiring to the internal wiring 22 of the embodiment 1; 43 denotes a similar bump to the bump 23 of the embodiment 1; 44 denotes a first integrated circuit chip bonded to the top surface of the substrate 41 by means of adhesion or the like, which is similar to the one integrated circuit chip 24 of the embodiment 1; 45 denotes an insulation layer formed on the top surface of the first integrated circuit chip 44; 46 denotes a wiring formed by means of lithography technology within the inside of the insulation layer 45 and on the top surface of the insulation layer 45 such that the wiring is connected with the internal wiring 42; and 47 denotes an insulation layer formed on the top surfaces of the insulation layer 45 and of the wiring 46.

Additionally, reference numeral 48 denotes a second integrated circuit chip disposed on the top surface of the insulation layer 47, which is similar to the other integrated circuit chip 24 of the embodiment 1; 49 denotes an insulation layer formed on the top surface of the second integrated circuit chip 48; 50 denotes a wiring formed by means of lithography technology within the in side of the insulation layer 49 and on the top surface of the insulation layer 49 such that the wiring is connected with the wiring 46 that is located below the wiring 50; and 51 denotes an insulation layer formed on the top surfaces of the insulation layer 49 and of the wiring 50.

In addition, reference numeral 52 denotes a third integrated circuit chip having a different function from the ones of the first integrated circuit chip 44 and of the second integrated circuit chip 48, disposed on the top surface of the insulation layer 51; 53 denotes an insulation layer formed on the third integrated circuit chip 52; 54 denotes a wiring formed within the inside of the insulation layer 53 and on the top surface of the insulation layer 53 by means of lithography technology such that the wiring is connect with the wiring 50 located below the wiring 54; 55 denotes a pad connected with the wiring 54 on the top surface of the insulation layer 53; 56 denotes an insulation layer formed on the top surfaces of the insulation layer 53 and of the wiring 54; and 57 denotes a bonding wire connected with the pad 55.

The manufacturing method of the multi-chip module will now be described as below.

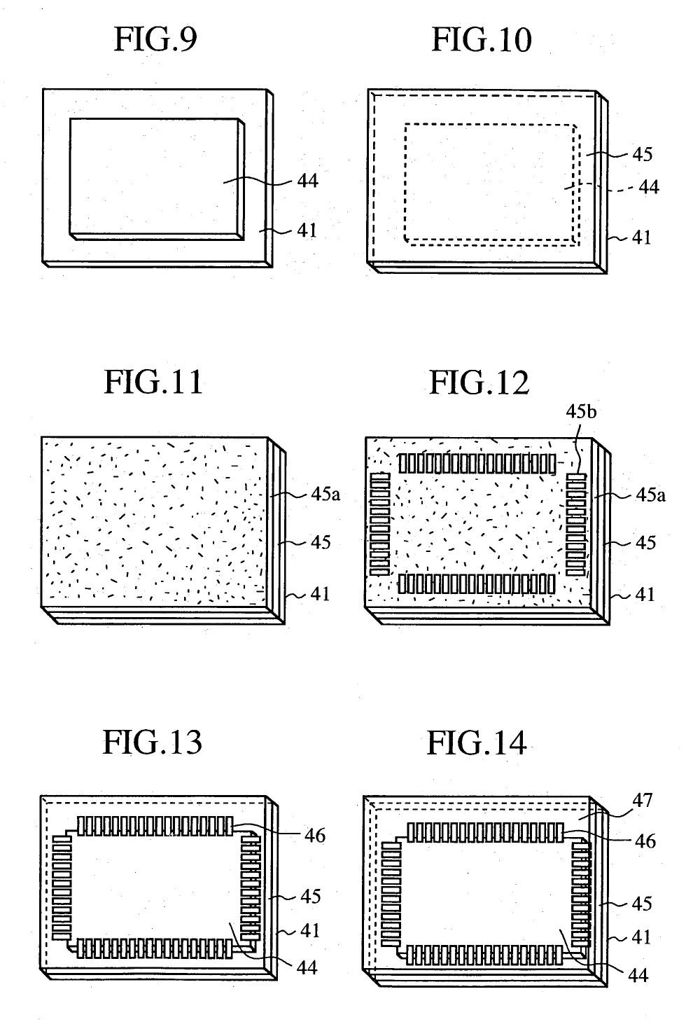

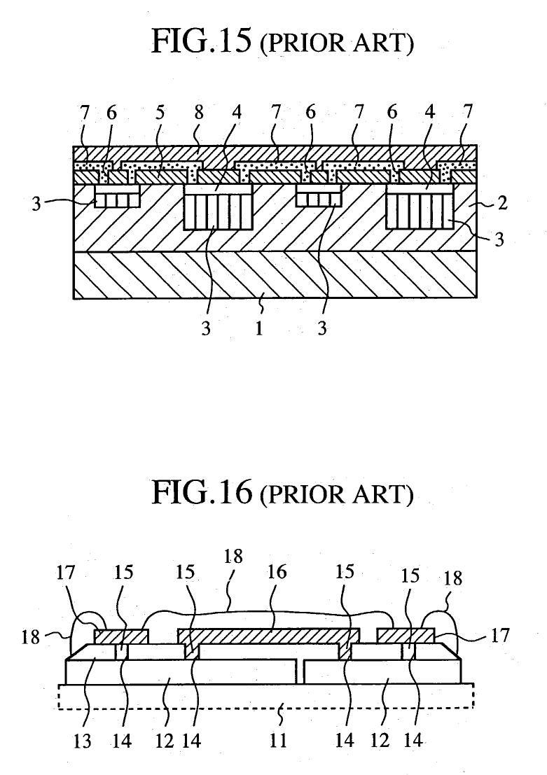

As shown in FIG. 9, the first integrated circuit chip 44 is bonded to a predetermined position on the top surface of the substrate 41. Then, as shown in FIG. 10, the insulation layer 45 is applied over the top surface of the first integrated circuit chip 44. As shown in FIG. 11, a photoresist is applied over the insulation layer 45, to thereby form photoresist film 45a.

Subsequently, a photomask (not shown) having the pattern of the wiring 46 thereon is aligned on the photoresist film, the photoresist film 45a is irradiated with light through the photomask, and the photoresist film 45a is thereby exposed to have the exposed pattern of the wiring 46 therein. Then, when developing the photoresist film 45a with the solvent, the unexposed portion of the photoresist film 45a is solved therein, to thereby form wiring holes 45b to be used for forming the wiring 46 therethrough as shown in FIG. 12.

After that, aluminum, for instance, serving as the material of the wiring 46 is deposited within the wiring holes 45b by means of evaporation or plating, to thereby fill the wiring holes therewith. When removing the remaining photoresist film 45a by means of etching the film, only the fine wiring 46 used for electrically connecting the first integrated circuit chips 44 and the internal wiring 42 remains as shown in FIG. 13. Subsequently, as shown in FIG. 14, the insulation layer 45 and the wiring 46 are coated with the insulation layer 47, and thereby protected therewith.

The second integrated circuit chip 48 and the third integrated circuit chip 52 are also mounted on the substrate by means of similar lithography technology to the above-mentioned technology. That is, the second integrated circuit chip 48 is bonded to the top surface of the insulation layer 47; the insulation layer 49 is formed on the top surface of the second integrated circuit chip 48; the wiring 50 is formed inside the insulation layer 49 and on the top surface of the insulation layer 49; and the insulation layer 49 and the wiring 50 are protected by use of the insulation layer 51. Subsequently, the third integrated circuit chip 52 is bonded to the top surface of the insulation layer 51; the insulation layer 53 is formed on the top surface of the third integrated circuit chip 52; the wirings 54 and the pads 55 formed within the inside of the insulation layer 53 and on the top surface of the insulation layer 53; the insulation layer 53 and the pads 55 are protected by use of the insulation layer 56; and the bonding wires 57 are connected with the pads 55.

As mentioned above, in accordance with the embodiment 5, because the integrated circuit chips 44, 48, and 52 are mounted on the substrate 41 vertically with respect to the top surface of the substrate, the area within the substrate 41 which is used for mounting the integrated circuit chips 44, 48, and 52 can be reduced, thereby improving the design flexibility. In the embodiment 5, the similar effect to that of the embodiment 1 is obtained except the effect exerted by the spacer 25 in the embodiment 1.

What is claimed is:

1. A multi-chip module comprising a plurality of integrated circuit chips that are disposed on a substrate such that each of the top surfaces of the plurality of integrated circuit chips is located within the same plane, in which at least the wiring between the plurality of integrated circuit chips is formed by means of lithography technology, wherein a material having substantially the same coefficient of thermal expansion as that of the integrated circuit chips is disposed between the integrated circuit chips, and the wiring is formed on the material.

2. A multi-chip module according to claim 1, wherein the top surface of the material is located within the same plane.

3. A multi-chip module according to claim 1, wherein there is not any gap between the material and the integrated circuit chips.

4. A multi-chip module according to claim 1, wherein the material is a different substance from the integrated circuit chip.

5. A multi-chip module according to claim 1, wherein the material constitutes a portion of the integrated circuit chip.

6. A multi-chip module according to claim 1, wherein the material is a spacer that is of rectangular cross-section.

7. A multi-chip module according to claim 1, wherein the material is a spacer that is of triangular cross-section.

8. A multi-chip module according to claim 1, wherein the substrate is provided with an internal wiring, the material is provided with a through hole, and the wiring and the internal wiring are connected by use of the through hole.
